(19) United States
(12) Patent Application Publication
(10) Pub. No.: US 2009/0262526 A1
(43) Pub. Date: Oct. 22, 2009

(54) White Light Emitting Diode Module

(75) Inventors: Yu-Ping Lin, Taoyuan City (TW); Chih-Yuan Chen, Yangmei Town (TW); Pei-Ju Lai, Chiayi City (TW); Ding-He Chen, Chupei City (TW)

Correspondence Address: THOMAS, KAYDEN, HORSTEMEYER & RISLEY, LLP, 600 GALLERIA PARKWAY, S.E., STE 1500, ATLANTA, GA, 30339-5994, US

(73) Assignee: KiSmart Corp., Taipei City (TW)

(21) Appl. No.: 12/104,708

(22) Filed: Apr. 17, 2008

(51) Int. Cl. F21V 9/02; H01L 27/28

(52) U.S. Cl. 362/231; 313/504

(57) ABSTRACT

The white LED module includes a packaging housing having a containing chamber, an LED chipset disposed in the containing chamber, and a shared flat wavelength-converting structure disposed on the packaging housing. The LED chipset could illuminate an original light with at least two wavelengths. The original light may be diffused with the shared flat wavelength-converting structure and may be partially converted into a converted light with the shared flat wavelength-converting structure. The converted light and the original light are mixed to form a white light.

### BACKGROUND

1. Field of Invention

The present invention relates to a white light emitting diode (LED) module. More particularly, the present invention relates to a white LED module with high color rendering property.

2. Description of Related Art

Light emitting diodes (LEDs) with excellent durability, long operation life, low power consumption, containing no mercury and potentially high efficiency have become a promising device for general-purpose illumination applications. White LED is an illumination light source that is good for environmental protection and energy saving. Recently, LEDs have increasingly been used in the illumination field for electronic devices. For example, LEDs are popularly used in the mobile phones, personal digital assistants (PDAs) and so on.

A conventional structure to form the white LED is to mix a phosphor in the packaging resin, which is filled in a chamber in which the blue LED chip is disposed. The phosphor, such as YAG, could excite a part of the blue light into the yellow light, and the blue light and the yellow light could mix to form the white light. However, the color rendering property is poor in this type of white LED. Some white LED may includes blue LED chip with YAG and SrS phosphor, or the blue LED with SrS and SrGa₂S₄ phosphor. However, the efficiency and the life of SrS and SrGa₂S₄ phosphor are not as well as the YAG phosphor. Furthermore, the heat generated by the LED chip would conduct to the resin and the phosphor, and the efficiency and the life of the phosphor would be reduced.

Another type of the white LED is to adopt a red LED chip, a green LED chip and a blue LED chip packed together in a packing structure so as to mix the three colors to form the white light. The white light mixed with three colors has less color rendering property at the edge of the white LED.

### SUMMARY

The present invention is directed to a white LED module, that satisfies this need to improve the color rendering property of the white LED module.

The white LED module includes a packaging housing having a containing chamber, an LED chipset disposed in the containing chamber, and a shared flat wavelength-converting structure disposed on the packaging housing. The LED chipset could illuminate an original light with at least two wavelengths. The original light may be diffused with the shared flat wavelength-converting structure and may be partially converted into a converted light with the shared flat wavelength-converting structure. The converted light and the original light are mixed to form a white light.

It is to be understood that both the foregoing general description and the following detailed description are by examples, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 is a cross-section diagram of an embodiment of the white LED module of the invention.

FIG. 2A is a color temperature diagram of the conventional white LED with three-color LED chips.

FIG. 2B is a color temperature diagram of the embodiment of the white LED module with the shared flat wavelength-converting structure of the invention.

FIG. 3 is a cross-section diagram of another embodiment of the white LED module of the invention.

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

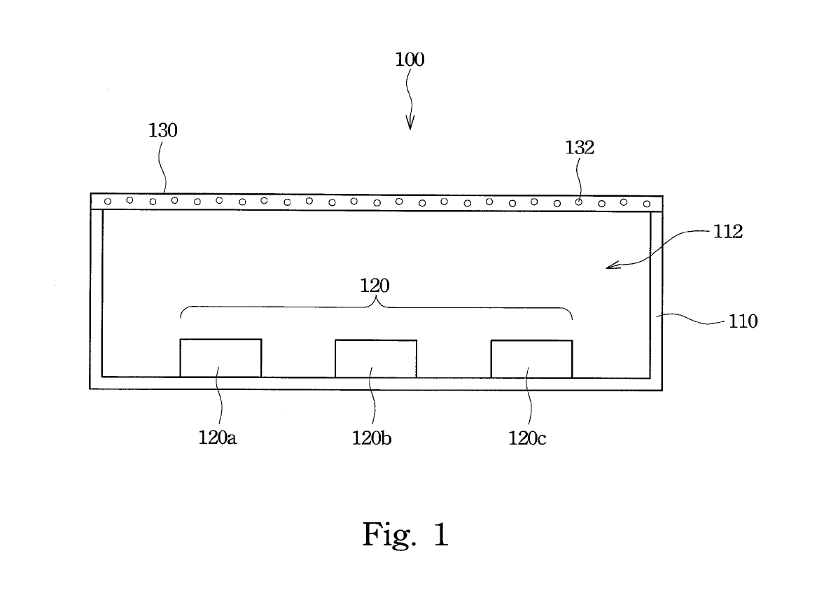

Refer to FIG. 1. FIG. 1 illustrates a cross-sectional diagram of an embodiment of the white LED module of the invention. The white LED module 100 includes a packaging housing 110, an LED chipset 120, and a shared flat wavelength-converting structure 130. The packaging housing 110 has a containing chamber 112. The LED chipset 120 is disposed in the containing chamber 112. The shared flat wavelength-converting structure 130 is disposed on the packaging housing 110 to seal the containing chamber 112.

The LED chipset 120 includes a plurality of LED chips. The LED chipset 120 in this embodiment may include a first LED chip 120a, a second LED chip 120b, and a third LED chip 120c. The first LED chip 120a may illuminate a first light with a first wavelength. The second LED chip 120b may illuminate a second light with a second wavelength. The third LED chip 120c may illuminate a third light with a third wavelength. The first light, the second light, and the third light may include a visible light or an invisible light. For example, the first light illuminating from the first LED chip 120a may be a blue light with the first wavelength about 440 nm to 480 nm. The second light illuminating from the second LED chip 120b may be a green light with the second wavelength about 510 nm to 550 nm. The third light illuminating from the third LED chip 120c may be a red light with the third wavelength about 600 nm to 630 nm. The first LED chip 120a, the second LED chip 120b, and the third LED chip 120c may be linearly arranged in the containing chamber 112 in this embodiment.

The shared flat wavelength-converting structure 130 is disposed at the emitting side of the white LED module 100. The first light, the second light, and the third light from the LED chipset 120 may illuminate to the shared flat wavelength-converting structure 130 and be diffused by the shared flat wavelength-converting structure 130 for equal illumination. The shared flat wavelength-converting structure 130 includes a phosphor 132 scattered within. The phosphor 132 of the shared flat wavelength-converting structure 130 may excite a part of the first light and converts the same part of the first light into a fourth light with a fourth wavelength different from the first wavelength. The first light, the second light, the third light, and the fourth light are mixed to form a white light at the shared flat wavelength-converting structure 130.

The fourth wavelength of the fourth light may be different from the second wavelength of the second light and the third wavelength of the third light. For example, the phosphor 132 may consist of single powder, such as YAG, and the fourth light may be a yellow light with a wavelength of about 560 nm to 600 nm. The fourth wavelength of the fourth light may overlap the second wavelength of the second light and the third wavelength of the third light. For example, the phosphor 132 may consist of multi powder, such as a combination of YAG, SrS, and SrGa₂S₄, and the fourth light may be a combination of the yellow light, the red light, and the green light.

The phosphor 132 may include YAG, SrS, SrGa2S4, Eu₂O₃, Y₂O₃, . . . etc. The phosphor 132 may be selected as the requirement to excite the visible light or the invisible light from the LED chipset 120.

The fourth light can almost complete the lack wavelength of the original light illuminating from the LED chipset 120, and the white light mixed by the first light, the second light, the third light, and the fourth light in this embodiment may have better color rendering property than the conventional white LED, which is without the shared flat wavelength-converting structure 130.

Unlike the conventional white LED, the white LED module 100 of the invention does not include the packaging resin mixed with the phosphor filling in the containing chamber 112. The shared flat wavelength-converting structure 130 with the phosphor 132 is disposed on the packaging housing 110 and does not touch the LED chipset 120. The heat generated by the LED chipset 120 may not conduct to the shared flat wavelength-converting structure 130, thus the phosphor 132 in the shared flat wavelength-converting structure 130 may have a lower heated temperature, and the life of the shared flat wavelength-converting structure 130 may be extended.

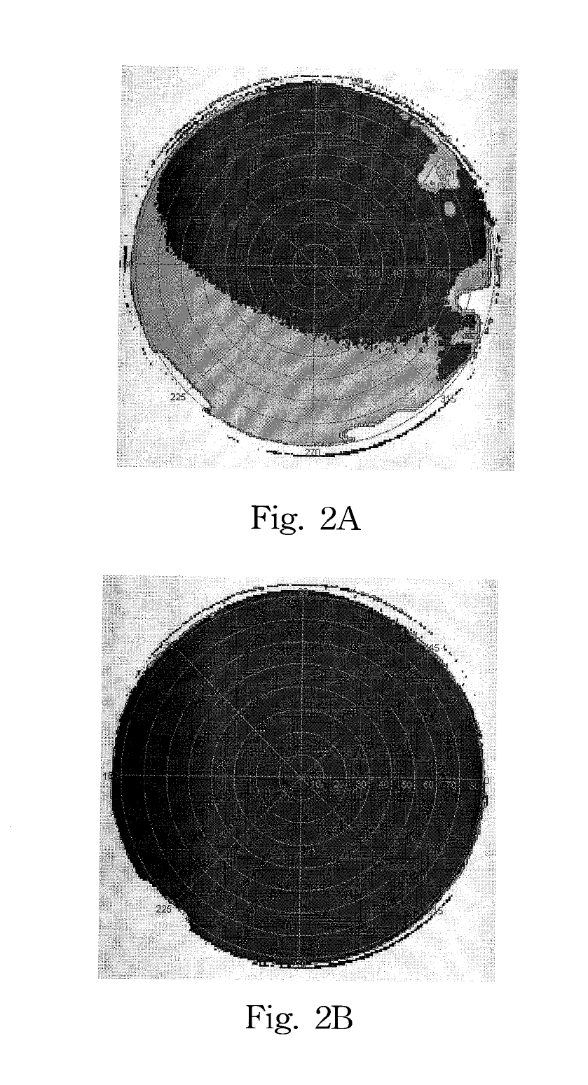

Refer to FIG. 2A and FIG. 2B. FIG. 2A is a color temperature diagram of the conventional white LED with three-color LED chips. FIG. 2B is a color temperature diagram of the embodiment of the white LED module with the shared flat wavelength-converting structure of the invention. Refer to FIG. 1 simultaneously, the original light illuminating from the LED chipset 120 are diffused by the shared flat wavelength-converting structure 130, and the white light may be mixed by the original light and the converted light more equally. The color temperature of the white LED module 100 with the shared flat wavelength-converting structure 130 shown in FIG. 2B is more uniform than the color temperature of the conventional white LED with three-color LED chips shown in FIG. 2A.

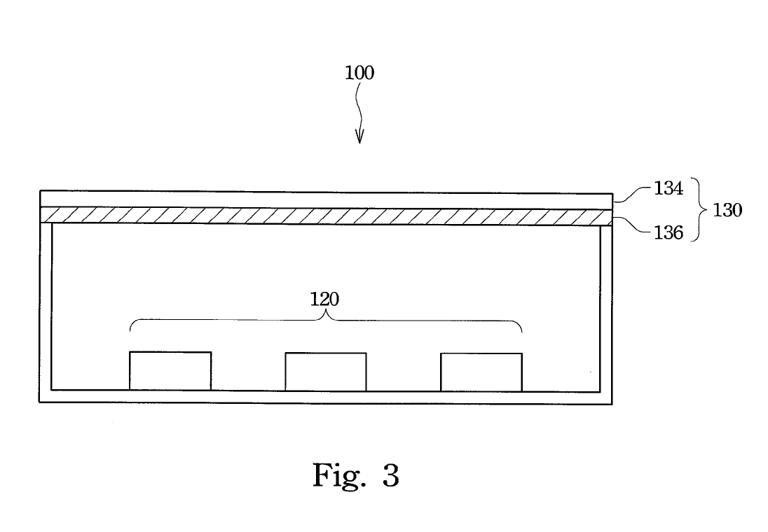

Refer to FIG. 3. FIG. 3 illustrates a cross-sectional diagram of another embodiment of the white LED module of the invention. The LED chipset 120 may illuminate the original light. The LED chipset 120 includes LED chips with at least two different colors. The original light illuminated from the LED chipset 120 includes at least two different wavelengths. The shared flat wavelength-converting structure 130 may diffuse the original light equally and may partially convert the original light into the converted light. The original light and the converted light are mixed into the white light.

The original light may include visible light. The original light may include the red light, the green light, the blue light, or the combination thereof. The original light may further include an invisible light, such as an ultraviolet light. The LED chipset 120 may be selected from the group consisting of the red light LED chip, the green light LED chip, the blue light LED chip, the ultraviolet LED chip, and the combination thereof.

The shared flat wavelength-converting structure 130 may include a substrate 134 and a wavelength-converting material 136 coated on the substrate 134. The wavelength-converting material 136 may be coated on an inner surface or on an outer surface of the substrate 134.

The wavelength-converting material 136 may include phosphor powder, photo luminescent layer, fluorescent color-conversion-media, organic complex material, luminescent pigments, quantum dots-based material, quantum wire-based material or quantum well-based material, or the combination thereof. The substrate 134 may be a transparent film. The material of the substrate 134 may include PC (Polycarbonate), PMMA (polymethyl methacrylate), MS (methyl styrene), PET (polyethylene terephthalate), quartz or glass.

The wavelength converting material 136 may be coated on the substrate 134 with a roll-to-roll process, a dip coating process, a comma coating process, a spraying coating process, a spin coating process, a slot coating process, a curtain coating process, or a gravure coating process.

The original light illuminating form the LED chipset may be diffused with the shared flat wavelength-converting structure and may be partially converted into the converted light with the shared flat wavelength-converting structure. The converted light may almost complete the lack wavelength of the original wavelength to form the white light with boarder wavelength. The color rendering property of the white LED module can be improved with the shared flat wavelength-converting structure. The driving current of each LED chip, the variety and number of the LED chips, and the variety of the phosphor can be altered as the requirement to adjust the color rendering property of the white LED module.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A white light emitting diode (LED) module comprising:
a packaging housing having a containing chamber;
an LED chipset disposed in the containing chamber, comprising:
a first LED chip for illuminating a first light with a first wavelength, and
a second LED chip for illuminating a second light with a second wavelength; and
a shared flat wavelength-converting structure disposed on the packaging housing for diffusing the first light and the second light equally, wherein the shared flat wavelength-converting structure partially converts the first light into a fourth light with a fourth wavelength different from the first wavelength, and the first light, the second light, and the fourth light are mixed to form a white light.

2. The white LED module of claim 1, wherein the first light and the fourth light comprise a visible light.

3. The white LED module of claim 2, wherein the first light is a blue light, and the fourth light is selected from a group consisting of a yellow light, a red light, a green light, and the combination thereof.

4. The white LED module of claim 1, wherein the first light comprises an invisible light.

5. The white LED module of claim 1, wherein the shared flat wavelength-converting structure comprises a substrate, and a wavelength-converting material coated on the substrate.

6. The white LED module of claim 5, wherein the wavelength-converting material comprises phosphor powder, photo luminescent layer, fluorescent color-conversion-media, organic complex material, luminescent pigments, quantum dots-based material, quantum wire-based material, quantum well-based material, or the combination thereof.

7. The white LED module of claim 5, wherein the substrate is a transparent film.

8. The white LED module of claim 5, wherein the material of the substrate comprises PC (Polycarbonate), PMMA (polymethyl methacrylate), MS (methyl styrene), PET (polyethylene terephthalate), quartz, or glass.

9. A white light emitting diode (LED) module comprising:
a packaging housing having a containing chamber;
an LED chipset disposed in the containing chamber for illuminating a plurality of original light, wherein the original light comprises at least two wavelengths; and
a shared flat wavelength-converting structure disposed on the packaging housing for diffusing the original light equally, wherein the shared flat wavelength-converting structure partially converts the original light into a converted light, and the original light and the converted light are mixed into a white light.

10. The white LED module of claim 9, wherein the original light comprises a visible light.

11. The white LED module of claim 9, wherein the original light comprises an invisible light.

12. The white LED module of claim 9, wherein the shared flat wavelength-converting structure comprises a substrate, and a wavelength-converting material coated on the substrate.

13. The white LED module of claim 12, wherein the wavelength-converting material comprises phosphor powder, photo luminescent layer, fluorescent color-conversion-media, organic complex material, luminescent pigments, quantum dots-based material, quantum wire-based material, quantum well-based material, or the combination thereof.

14. The white LED module of claim 12, wherein the substrate is a transparent film.

15. The white LED module of claim 12, wherein the material of the substrate comprises PC (Polycarbonate), PMMA (polymethyl methacrylate), MS (methyl styrene), PET (polyethylene terephthalate), quartz, or glass.
